(19) United States
(12) Patent Application Publication
(10) Pub. No.: US 2012/0155171 A1
(43) Pub. Date: Jun. 21, 2012

(54) MEMORY SYSTEM

(76) Inventors: Yuji KOMINE, Hino-shi (JP); Tokumasa Hara, Kawasaki-shi (JP)

(21) Appl. No.: 13/242,958

(22) Filed: Sep. 23, 2011

(30) Foreign Application Priority Data
Dec. 17, 2010 (JP) 2010-281387

(51) Int. Cl. G11C 14/00

(52) U.S. Cl. 365/185.08

(57) ABSTRACT

According to one embodiment, a memory system includes a nonvolatile first memory configured to store a boot program, a volatile second memory, a detection circuit configured to detect a level of a power supply voltage, and to generates an interrupt when the power supply voltage becomes less than a first level, and a state machine configured to execute a sequence including a first read operation for reading the boot program from the first memory and a transfer operation for transferring the read boot program to the second memory at power-on. The state machine includes a waiting state for waiting until the interrupt is deactivated when the interrupt is activated during the first read operation or the transfer operation.

### CROSS-REFERENCE TO RELATED APPLICATIONS

This application is based upon and claims the benefit of priority from prior Japanese Patent Application No. 2010-281387, filed Dec. 17, 2010, the entire contents of which are incorporated herein by reference.

### FIELD

Embodiments described herein relate generally to a memory system.

### BACKGROUND

A NAND flash memory is known as a type of a nonvolatile semiconductor memory. When a host apparatus uses a program stored in a nonvolatile semiconductor memory (for example, a NAND flash memory), the program is transferred to a volatile semiconductor memory whose operation speed is faster than the NAND flash memory (for example, an SRAM), and the program stored in the SRAM is used by the host apparatus. By doing the above sequence, the host apparatus can read the program at a fast speed.

In order to normally operate the NAND flash memory and the SRAM, it is necessary to operate the NAND flash memory and the SRAM with a particular guaranteed voltage or more. In particular, when the operation voltage of the SRAM and the like is low, data cannot be retained.

When the program is transferred from the NAND flash memory to the SRAM with a power supply voltage lower than the guaranteed voltage, data are erroneously transferred, and an incorrect program is stored in the SRAM. As a result, the incorrect program may be executed by the host apparatus.

### BRIEF DESCRIPTION OF THE DRAWINGS

FIG. 1 is a block diagram illustrating a configuration of a memory system 1;

FIG. 2 is a block diagram illustrating a configuration of a NAND flash memory 10;

FIG. 3 is a circuit diagram illustrating a configuration of one block BLK;

FIG. 4 is a state transition diagram illustrating operation of a state machine 12 according to a first embodiment;

FIG. 5 is a timing diagram illustrating a first example of power-on sequence according to the first embodiment;

FIG. 6 is a timing diagram illustrating a second example of a power-on sequence;

FIG. 7 is a timing diagram illustrating a third example of a power-on sequence;

FIG. 8 is a timing diagram illustrating a fourth example of a power-on sequence;

FIG. 9 is a state transition diagram illustrating operation of a state machine 12 according to a second embodiment; and

FIG. 10 is a timing diagram illustrating a power-on sequence according to the second embodiment.

### DETAILED DESCRIPTION

In general, according to one embodiment, there is provided a memory system comprising:

a nonvolatile first memory configured to store a boot program;

a volatile second memory;

a detection circuit configured to detect a level of a power supply voltage, and to generates an interrupt when the power supply voltage becomes less than a first level; and

a state machine configured to execute a sequence including a first read operation for reading the boot program from the first memory and a transfer operation for transferring the read boot program to the second memory at power-on,

wherein the state machine includes a waiting state for waiting until the interrupt is deactivated when the interrupt is activated during the first read operation or the transfer operation.

The embodiments will be described hereinafter with reference to the accompanying drawings. In the description which follows, the same or functionally equivalent elements are denoted by the same reference numerals, to thereby simplify the description.

A memory system according to the present embodiment is configured such that a nonvolatile semiconductor memory serving as a main memory unit and a volatile memory capable of being read faster than the nonvolatile semiconductor memory are integrated into one chip. In the explanation below, a NAND flash memory is used as an example of a nonvolatile semiconductor memory, and a static random access memory (SRAM) is used as an example of a volatile memory.

### First Embodiment

FIG. 1 is a block diagram illustrating a configuration of a memory system 1 according to the first embodiment. The memory system 1 includes a NAND flash memory 10, an SRAM 11, a state machine 12, a voltage level detection circuit 13, an input/output pad I/O, and pads P1 and P2. In the memory system 1, the NAND flash memory 10 functions as a main memory unit, and the SRAM 11 functions as a data buffer. The memory system 1 is connected to a host controller 2 via pads.

The memory system 1 receives a power supply voltage VCC from the outside, and operates using the power supply voltage VCC. The power supply voltage VCC is provided to each circuit including the voltage level detection circuit 13. The voltage level detection circuit 13 detects the level of the power supply voltage VCC. Then, the voltage level detection circuit 13 sends a detection result to the state machine 12, and generates an interrupt to the state machine 12 based on the detection result.

The input/output pad I/O receives data (including commands and addresses) from the host controller 2. The command and the address received by the input/output pad I/O are sent to the state machine 12, and the data other than the command and the address are sent to the SRAM 11. The data read from the SRAM 11 are output via the input/output pad I/O to the host controller 2.

Pad P1 receives various kinds of control signals CNT from the host controller 2. The control signal CNT input to pad P1 is sent to the state machine 12. Pad P2 receives a ready/busy signal RY/BY from the state machine 12. The ready/busy signal RY/BY is output to the host controller 2 via pad P2.

The state machine 12 controls overall operation of the memory system 1. Further, the state machine 12 controls various kinds of operations and sequences in the memory system 1 based on the command, the address, and control signal.

The SRAM 11 includes an SRAM cell array, a row decoder, a sense amplifier, and a data buffer for temporarily storing read data and write data. The SRAM cell array includes a plurality of memory cells (SRAM cells) arranged in a matrix form at each crossing regions of pairs of a plurality of word lines and a plurality of bit lines.

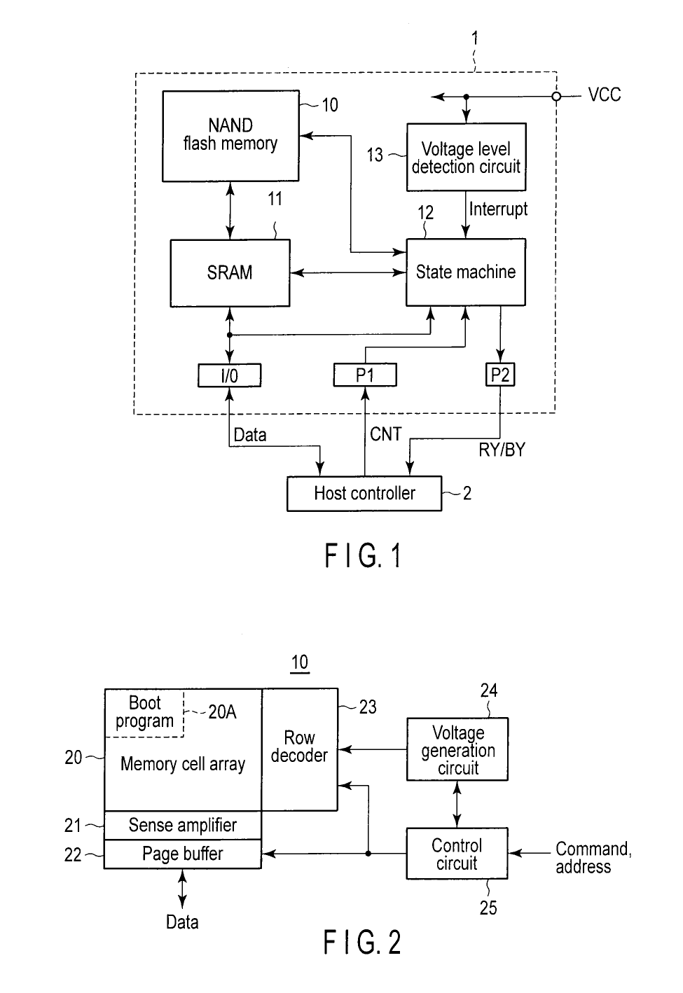

FIG. 2 is a block diagram illustrating a configuration of the NAND flash memory 10. The NAND flash memory 10 includes a memory cell array 20, a sense amplifier 21, a page buffer 22, a row decoder 23, a voltage generation circuit 24, and a control circuit 25.

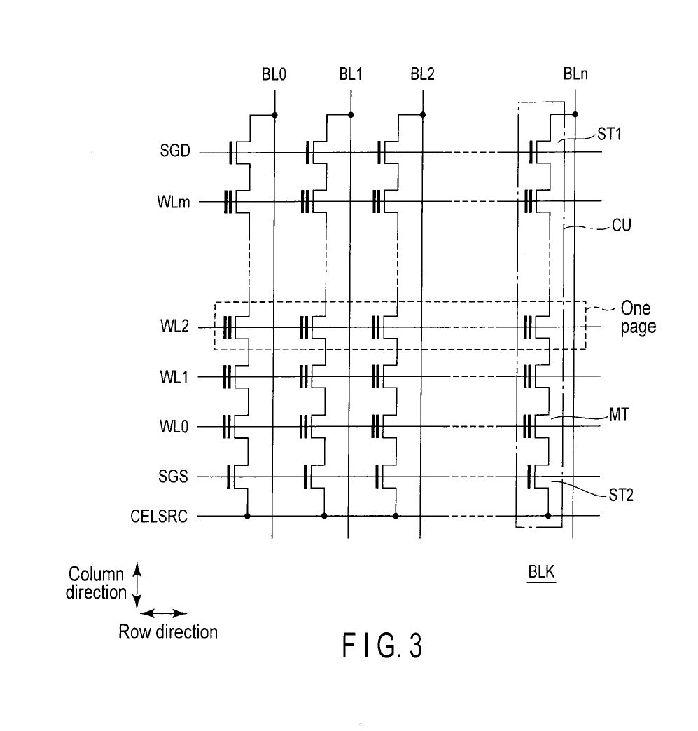

The memory cell array 20 includes a storage region 20A storing a boot program. The boot program is a program used when the host controller 2 is activated (booted). The memory cell array 20 includes a plurality of blocks BLK, i.e., units of data erase operations. FIG. 3 is a circuit diagram illustrating a configuration of one block BLK.

The block BLK includes a plurality of memory cell units CU. Each memory cell unit CU includes a plurality of memory cell transistors (which may be simply referred to as memory cells) MT and two select transistors ST1 and ST2. The memory cell transistor MT has a laminated gate structure including a charge storage layer (for example, floating gate electrode) formed on a semiconductor substrate with a gate insulating film interposed therebetween and a control gate electrode formed on the charge storage layer with an intergate insulating film interposed therebetween. The memory cell transistor MT is not limited to a floating gate structure. For example, the memory cell transistor MT may have a metal-oxide-nitride-oxide-silicon (MONOS) structure that uses a method for trapping electrons in an insulating film (for example, a nitride film) serving as a charge storage layer.

Current paths of the memory cell transistors MT which are adjacent to each other in one memory cell unit are connected in series. In other words, (m+1) memory cell transistors MT are connected in series in a column direction such that a diffusion region (source region or drain region) is shared by memory cell transistors MT adjacent to each other. The drain at one end side of the memory cell transistors MT connected in series is connected to a source of a select transistor ST1, and the source at the other end side thereof is connected to a drain of a select transistor ST2.

The control gate electrodes of the memory cell transistors MT in the same row are commonly connected to any one of a plurality of word lines WL0 to WLm. The gate electrodes of select transistors ST1 and ST2 in the same row respectively are connected commonly to select gate lines SGD and SGS, respectively. The drain of each select transistor ST1 is connected to any one of a plurality of bit lines BL0 to BLn. The source of each select transistor ST2 is commonly connected to a source line CELSRC.

A page is constituted by a plurality of memory cell transistors MT connected in the same word line WL. A data write/read operation is performed on the memory cell transistor MT in one page at a time.

The bit lines BL commonly connect the drains of select transistors ST1 between the blocks BLK. In other words, the memory cell units CU in the same column in the plurality of blocks BLK are connected to the same bit line BL.

For example, each memory cell transistor MT can store one bit of data in accordance with a threshold voltage caused by variation in the number of electrons injected into the floating gate electrode. The control of the threshold voltage may be performed by further dividing the levels, so that two bits of data or more may be stored in each memory cell transistor MT.

In FIG. 2, the bit lines BL are connected to the sense amplifier 21. The sense amplifier 21 controls the voltage of the bit lines BL to erase data in a memory cell, write data to a memory cell, and read data from a memory cell. The page buffer 22 temporarily stores read data read from the memory cell array 20, and temporarily stores write data to be written to the memory cell array 20.

The word lines WL are connected to the row decoder 23. The row decoder 23 selects a word line WL, and further applies various kinds of voltages to the word line WL that are needed to erase, write, and read data. The voltage generation circuit 24 boosts the power supply voltage VCC to generate various kinds of voltages used by the row decoder 23.

The control circuit 25 controls overall operation of the NAND flash memory 10. In other words, the control circuit 25 uses the command, the address, and the like to control erase, write, and read operations.

### Operation

When the power supply voltage VCC reaches a certain level after power-on, the memory system 1 performs the following three operations.
(1) Initialization data determining operation setting of the NAND flash memory 10 are read from the memory cell array 20 (hereinafter referred to as a power-on ROM [POR] read). (2) Subsequently, a boot program is read from the NAND flash memory 10 (hereinafter referred to as boot read). (3) Subsequently, the read boot program is transferred to the SRAM 11. The above series of operation is referred to as a power-on sequence. It should be noted that the POR read also includes initializing operation within the NAND flash memory 10 using initialization data.

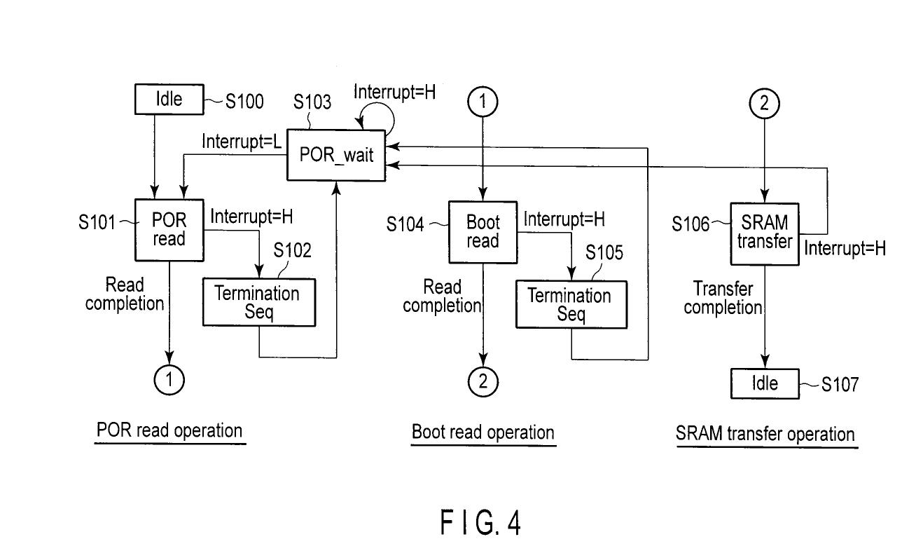

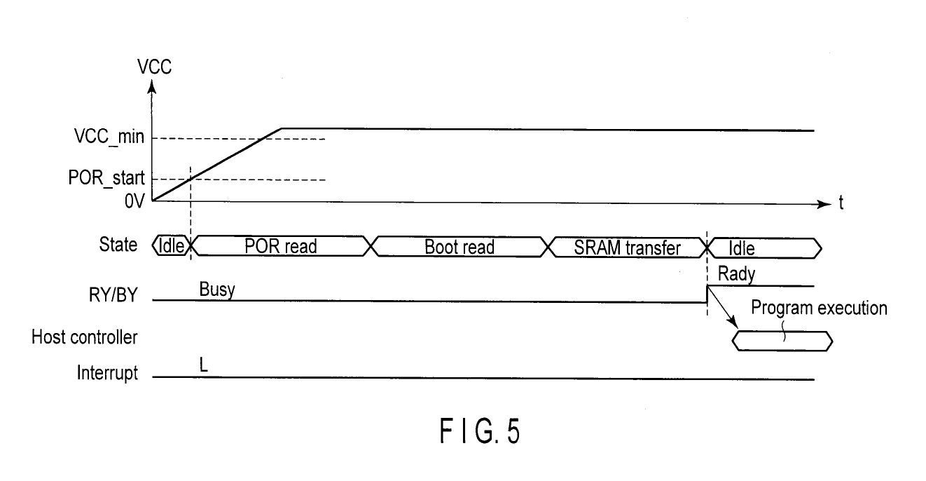

FIG. 4 is a state transition diagram illustrating operation of the state machine 12. FIG. 5 is a timing diagram illustrating a first example of power-on sequence and illustrating a basic operation of the memory system 1. In other words, the first example relates to operation of the memory system 1 when the power supply voltage VCC hardly varies.

When the power is turned on, the state machine 12 outputs a busy signal indicating execution of the power-on sequence to the host controller 2 via pad P2. Subsequently, the voltage level detection circuit 13 starts monitoring the power supply voltage VCC. When the voltage level detection circuit 13 detects that the power supply voltage VCC has reached a POR start level (POR_start), this detection result is sent to the state machine 12.

When the power supply voltage VCC reaches the POR start level (POR_start), the state machine 12 changes from an idle state S100 to a POR read state S101, and the POR read operation is executed. More specifically, the state machine 12 issues a command for reading the initialization data to the NAND flash memory 10. In response to this, the control circuit 25 reads the initialization data from the memory cell array 20, and uses the initialization data to execute the initializing operation. Thereafter, the NAND flash memory 10 sends a notification indicating completion of the POR read operation to the state machine 12.

When the POR read operation is completed, the state machine 12 changes to a boot read state S104, and executes boot read operation. More specifically, the state machine 12 issues a command and an address for reading the boot program to the NAND flash memory 10. In response to this, the control circuit 25 of the NAND flash memory 10 reads the boot program from the memory cell array 20, and temporarily stores the boot program to the page buffer 22. Thereafter, the NAND flash memory 10 sends a notification indicating completion of the boot read operation to the state machine 12.

When the boot read operation is completed, the state machine 12 changes to an SRAM transfer state S106, and executes the SRAM transfer operation. More specifically, the state machine 12 issues a command for transferring data from the NAND flash memory 10 to the SRAM 11 to the NAND flash memory 10 and the SRAM 11. In response to this, the control circuit 25 of the NAND flash memory 10 transfers the boot program stored in the page buffer 22 to the SRAM 11. The SRAM 11 stores the boot program transferred from the NAND flash memory 10 to the SRAM cell array. Thereafter, the SRAM 11 sends a notification of completion of the SRAM transfer operation to the state machine 12.

When the SRAM transfer operation is completed, the state machine 12 changes to an idle state S107. Subsequently, the state machine 12 outputs a ready signal indicating completion of a power-on sequence via pad P2 to the host controller 2. The host controller 2 recognizes the completion of the power-on sequence when receiving the ready signal. Thereafter, the host controller 2 executes boot processing using the boot program stored in the SRAM 11.

It should be noted that in the POR read state, only initial setting operation of the NAND flash memory 10 may be guaranteed, and the system is designed to be able to operate even at a low voltage, e.g., POR start level. On the other hand, at a low voltage, it is difficult to guarantee operation of the SRAM 11 in the SRAM transfer state and in the boot read state including a normal read operation of the NAND flash memory 10. Therefore, in the present embodiment, as shown in FIG. 5, an external guaranteed voltage VCC_min is defined as a voltage at which normal operation of the NAND flash memory 10 and the SRAM 11 is guaranteed. The external guaranteed voltage VCC_min is an external specification at which operation of the NAND flash memory 10 and the SRAM 11 is guaranteed, and has a value with a larger margin than an internal guaranteed voltage at which operation inside of the memory system 1 is guaranteed, e.g., LOWVDD, explained later.

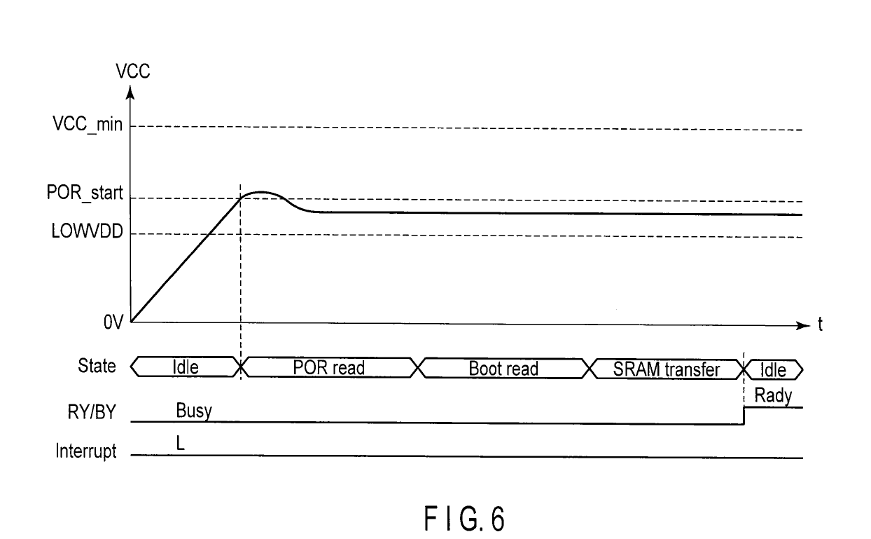

FIG. 6 is a timing diagram illustrating a second example of a power-on sequence. The second example relates to operation of the memory system 1 when the power supply voltage VCC drops to a voltage lower than a POR start level.

When the power is turned on, the state machine 12 outputs a busy signal to the host controller 2. Subsequently, the voltage level detection circuit 13 starts monitoring the power supply voltage VCC. When the power supply voltage VCC reaches the POR start level (POR_start), the state machine 12 changes from the idle state S100 to the POR read state S101, and the POR read operation is executed.

Subsequently, it is assumed that the power supply voltage VCC drops to a voltage lower than the POR start level. Although the voltage level detection circuit 13 keeps on monitoring the power supply voltage VCC, the voltage level detection circuit 13 does not generate any interrupt if the power supply voltage VCC is greater than or equal to an internal guaranteed voltage LOWVDD lower than the POR start level by a predetermined voltage. Therefore, in the second example, the same sequence as the first example is executed.

The internal guaranteed voltage LOWVDD is a voltage for guaranteeing operation inside of the memory system 1. In other words, as long as the memory system 1 operates at the internal guaranteed voltage LOWVDD or more, the NAND flash memory 10 and the SRAM 11 are respectively guaranteed to perform normal operation including a write operation and read operation. As described above, the internal guaranteed voltage LOWVDD is defined, and this can prevent erroneous data transfer between the NAND flash memory 10 and the SRAM 11 and erroneous data latch in the SRAM 11.

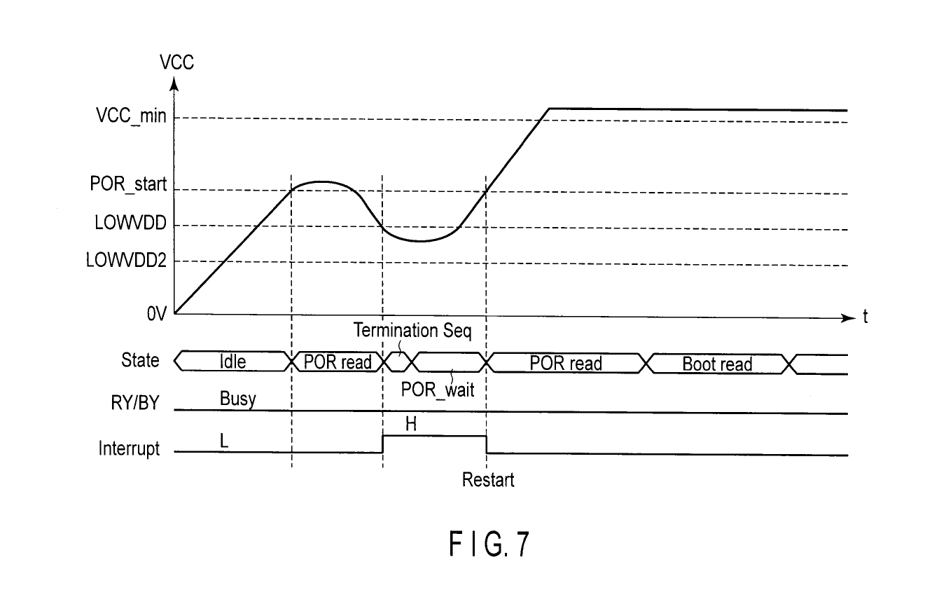

FIG. 7 is a timing diagram illustrating a third example of a power-on sequence. The third example relates to operation of the memory system 1 when the power supply voltage VCC drops to a voltage lower than voltage LOWVDD and an interrupt is generated.

When the power is turned on, the state machine 12 outputs a busy signal to the host controller 2. Subsequently, the voltage level detection circuit 13 starts monitoring the power supply voltage VCC. When the power supply voltage VCC reaches the POR start level (POR_start), the state machine 12 changes from the idle state S100 to the POR read state 5101, and the POR read operation is executed.

Subsequently, it is assumed that the power supply voltage VCC drops to a voltage lower than the POR start level. Although the voltage level detection circuit 13 keeps on monitoring the power supply voltage VCC, the voltage level detection circuit 13 cannot guarantee normal operation of the NAND flash memory 10 and the SRAM 11 when the power supply voltage VCC becomes less than voltage LOWVDD. In this case, the voltage level detection circuit 13 generates an interrupt to the state machine 12 (Interrupt=high).

When the interrupt is generated, the state machine 12 executes a termination sequence (termination Seq) S102. The termination sequence includes operation for resetting read processing of the NAND flash memory 10. More specifically, the termination sequence includes processing for resetting a voltage applied to a word line of the NAND flash memory 10 and processing for withdrawing charges transferred to a bit line. When a termination sequence S102 is completed, the state machine 12 changes to a waiting state (POR_wait) S103. In the waiting state S103, no operation is performed based on control of the state machine 12.

Subsequently, when the power supply voltage VCC reaches a level greater than or equal to the POR start level, the voltage level detection circuit 13 cancels the interrupt (Interrupt=low). When the interrupt is cancelled, the state machine 12 re-executes the power-on sequence from the beginning.

However, when the power supply voltage VCC drops to a voltage lower than the POR start level, the voltage level at which the power-on sequence can be re-executed is a voltage LOWVDD2 lower than voltage LOWVDD by a predetermined voltage. When the power supply voltage VCC becomes lower than voltage LOWVDD2, the state machine 12 deems this state as a power-off state, and terminates the power-on sequence. In this case, it is necessary to perform the power-on process again. In the contents described as being re-executed in the explanation below, it is assumed that the voltage drop of the power supply voltage VCC is greater than or equal to LOWVDD2 but less than LOWVDD in all cases.

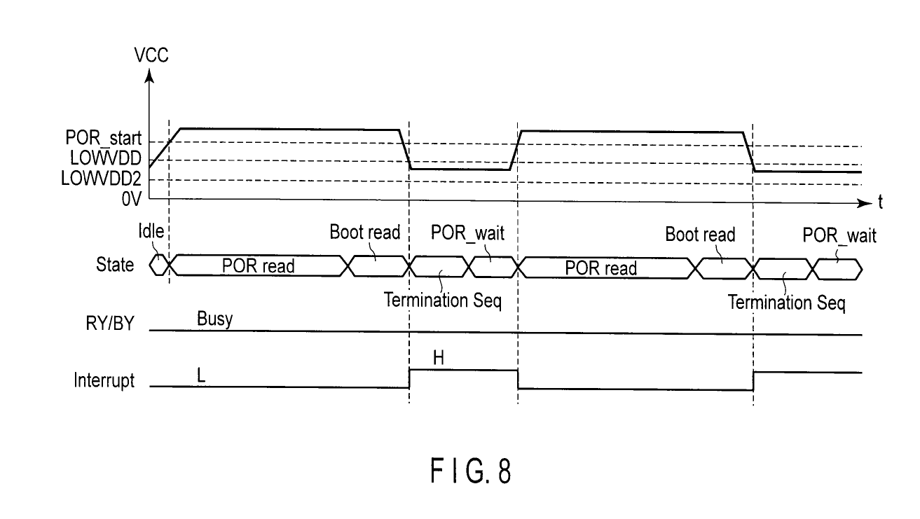

FIG. 8 is a timing diagram illustrating a fourth example of a power-on sequence. The fourth example relates to operation of the memory system 1 when the power supply voltage VCC drops to a voltage lower than a voltage LOWVDD in the boot read state.

When the power is turned on, the state machine 12 outputs a busy signal to the host controller 2. Subsequently, the voltage level detection circuit 13 starts monitoring the power supply voltage VCC. When the power supply voltage VCC reaches the POR start level (POR_start), the state machine 12 changes from an idle state S100 to a POR read state S101, and the POR read operation is executed.

When the POR read operation is completed, the state machine 12 changes to the boot read state S104, and executes the boot read operation. Subsequently, it is assumed that the power supply voltage VCC drops to a voltage lower than voltage LOWVDD during the boot read operation. Although the voltage level detection circuit 13 keeps on monitoring the power supply voltage VCC, the voltage level detection circuit 13 generates an interrupt (Interrupt =high) to the state machine 12 when the power supply voltage VCC is less than voltage LOWVDD.

When the interrupt is generated, the state machine 12 executes a termination sequence S105. The termination sequence S105 is the same operation as S102. When the termination sequence S105 is terminated, the state machine 12 changes to the waiting state (POR_wait) S103.

Subsequently, when the power supply voltage VCC reaches a level greater than or equal to the POR start level, the voltage level detection circuit 13 cancels the interrupt (Interrupt=low). When the interrupt is cancelled, the state machine 12 re-executes the power-on sequence from the beginning.

Likewise, as shown in FIG. 4, when the voltage level detection circuit 13 generates an interrupt in the SRAM transfer state, i.e., when the power supply voltage VCC drops to a voltage lower than voltage LOWVDD, the state machine 12 changes to the waiting state (POR_wait) 5103. Subsequently, when the power supply voltage VCC reaches a level greater than or equal to the POR start level, the voltage level detection circuit 13 cancels the interrupt (Interrupt=low). When the interrupt is cancelled, the state machine 12 re-executes the power-on sequence from the beginning.

### Effects

As described in detail, in the first embodiment, the voltage level detection circuit 13 monitors the power supply voltage VCC supplied to the memory system 1, and when the power supply voltage VCC reaches a level greater than or equal to the POR start level after the power is turned on, the memory system 1 executes the power-on sequence. In this power-on sequence, the POR read operation, the boot read operation, and the SRAM transfer operation are executed in order. When the power supply voltage VCC becomes less than the internal guaranteed voltage LOWVDD, the voltage level detection circuit 13 generates an interrupt to the state machine 12. Then, the interrupt is generated during the POR read operation, the boot read operation, or the SRAM transfer operation, the state machine 12 re-executes the power-on sequence from the beginning (POR read operation).

Therefore, according to the first embodiment, even when the power supply voltage VCC drops during the POR read operation, the boot read operation, or the SRAM transfer operation after the power is turned on, the boot program can be correctly transferred to the SRAM 11. Therefore, the host controller 2 can execute the boot operation using the correct program, thus capable of preventing erroneous operation of the host controller 2.

On the other hand, while the state machine 12 repeatedly re-execute the power-on sequence due to variation of the power supply voltage VCC, the state machine 12 keeps on outputting the busy signal to the host controller 2. Therefore, this prevents the host controller 2 from executing incorrect boot program.

### Second Embodiment

As described above, in the POR read state, only initial setting operation of the NAND flash memory 10 may be guaranteed, and the system is designed to be able to operate even at a low voltage, e.g., POR start level. On the other hand, the NAND flash memory 10 and the SRAM 11 are caused to operate at a voltage greater than or equal to the internal guaranteed voltage LOWVDD in the boot read state and the SRAM transfer state, for the purpose of preventing erroneous data transfer between the NAND flash memory 10 and the SRAM 11 and erroneous data latch in the SRAM 11 under the low voltage. Further, a time it takes to change from the POR start level to the external guaranteed voltage VCC_min is defined as a specification item for power-on, so that operation of the NAND flash memory 10 and the SRAM 11 can be guaranteed.

However, since the state machine 12 executes the POR read state, the boot read state, and the SRAM transfer state in order, the boot read state or the SRAM transfer state may be started before the power supply voltage VCC reaches the guaranteed voltage VCC_min if the state machine 12 does not have a certain function for detecting that the power supply voltage VCC has reached the guaranteed voltage VCC_min. For example, the above phenomenon may occur when the specification of the NAND flash memory 10 is changed whereby the POR read state takes a shorter time but the specification of the memory system 1 is not changed according to the NAND flash memory 10.

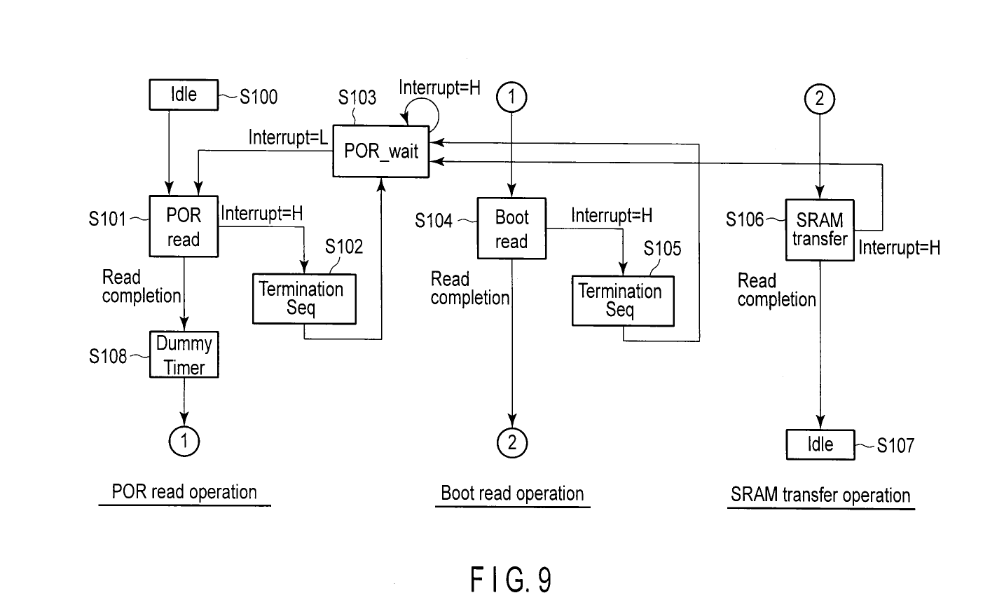

For this issue, the second embodiment is configured such that after the power supply voltage VCC reaches a voltage greater than or equal to the guaranteed voltage VCC_min, the boot read state or the SRAM transfer state is started. FIG. 9 is a state transition diagram illustrating operation of a state machine 12 according to the second embodiment. In FIG. 9, a dummy timer state S108 is inserted after a POR read state S101. Operations other than the dummy timer state S108 are the same as the first embodiment.

In the dummy timer state S108, no operation is performed by the control of the state machine 12, and the dummy timer state S108 is provided to cause the time when the power supply voltage VCC reaches the guaranteed voltage VCC_min to be the same as the time when the boot read state S104 is started. In other words, after the POR read state S101 is completed, the state machine 12 changes to the dummy timer state S108 and waits for a predetermined time. Then, the state machine 12 changes to the boot read state S104 after the predetermined time passes. In order to achieve the dummy timer state, the state machine 12 has a timer function. The waiting time of the timer is determined according to a rising speed of the power supply voltage VCC.

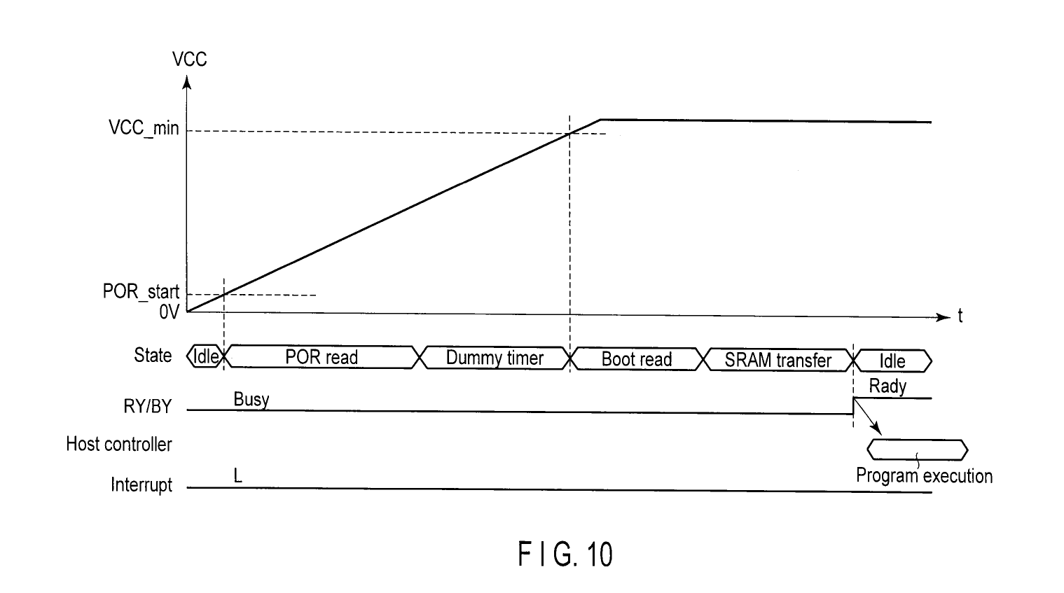

FIG. 10 is a timing diagram illustrating a power-on sequence according to the second embodiment. When the power is turned on, the state machine 12 outputs a busy signal to the host controller 2. Subsequently, the voltage level detection circuit 13 starts monitoring the power supply voltage VCC. When the power supply voltage VCC reaches the POR start level (POR_start), the state machine 12 changes from an idle state S100 to a POR read state S101, and the POR read operation is executed.

When the POR read operation is completed, the power supply voltage VCC has not yet reached the guaranteed voltage VCC_min. Subsequently, the state machine 12 changes to the dummy timer state S108 and waits for a predetermined time set by the timer. After the predetermined time passes, i.e., after the power supply voltage VCC reaches the guaranteed voltage VCC_min or more, the state machine 12 changes to the boot read state S104 to execute the boot read operation. The subsequent operations are the same as those of the first embodiment. The operation that occurs when an interrupt is generated because of change of the power supply voltage VCC is also the same as the first embodiment.

As described in detail, in the second embodiment, the boot read operation and the SRAM transfer operation can be executed using the power supply voltage VCC greater than or equal to the external guaranteed voltage VCC_min. Therefore, the boot program can be accurately transferred to the SRAM 11. Therefore, the host controller 2 can execute the boot operation using the correct program, thus capable of preventing erroneous operation of the host controller 2.

Even when the specification of the NAND flash memory 10 is changed whereby a time it takes to perform the POR read operation is changed, correct transfer operation of the boot program can be achieved without changing the circuit other than the NAND flash memory 10.

In each of the above embodiments, the NAND flash memory is explained as an example of the nonvolatile semiconductor memory storing the boot program. However, when the nonvolatile semiconductor memory storing the boot program does not need the POR read operation, the boot read operation and the SRAM transfer operation are executed in order after the power is turned on. The present embodiment can also be applied to the memory system having such nonvolatile semiconductor memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a nonvolatile first memory configured to store a boot program;
a volatile second memory;
a detection circuit configured to detect a level of a power supply voltage, and to generates an interrupt when the power supply voltage becomes less than a first level; and
a state machine configured to execute a sequence including a first read operation for reading the boot program from the first memory and a transfer operation for transferring the read boot program to the second memory at power-on,
wherein the state machine includes a waiting state for waiting until the interrupt is deactivated when the interrupt is activated during the first read operation or the transfer operation.

2. The system of claim 1, wherein the state machine re-executes the sequence after the waiting state is finished.

3. The system of claim 1, wherein the first level is an operation-guaranteed voltage of the first and second memories.

4. The system of claim 1, wherein the sequence includes a second read operation for reading initialization data for initializing the first memory from the first memory before the first read operation.

5. The system of claim 4, wherein the second read operation is executed after the power supply voltage reaches a second level.

6. The system of claim 1, wherein the state machine delays, by a first time, a time at which the first read operation is started.

7. The system of claim 6, wherein
the state machine starts the first read operation after the power supply voltage reaches a third level, and
the third level is obtained by adding a first margin to the first level.

8. The system of claim 6, wherein the first time is determined according to a rising speed of the power supply voltage.

9. The system of claim 6, wherein the sequence includes a second read operation for reading initialization data for initializing the first memory from the first memory before the first read operation.

10. The system of claim 9, wherein a operation for delaying the time is executed after the second read operation.

11. The system of claim 1, wherein
the detection circuit detects a fourth level of the power supply voltage, the fourth level being lower than the first level, and
the state machine terminates the sequence when the power supply voltage becomes less than the fourth level.

12. The system of claim 1, wherein the first and second memory is mounted on one chip.

13. The system of claim 1, wherein
the first memory is a NAND flash memory, and
the second memory is an SRAM.
